(19) United States
(12) Patent Application Publication
(10) Pub. No.: US 2026/0249612 A1
(43) Pub. Date: Aug. 27, 2026

(54) INKJET PRINTING HEAD, INKJET PRINTING DEVICE INCLUDING THE INKJET PRINTING HEAD, AND METHOD FOR MANUFACTURING INKJET PRINTING HEAD

(71) Applicant: Samsung Display Co., LTD., Yongin-si (KR)

(72) Inventors: JUNGHAN SEO, Yongin-si (KR); JAESIK KIM, Yongin-si (KR); WOO YONG SUNG, Yongin-si (KR); SEUNGHO YOON, Yongin-si (KR); BYEONGJUN LEE, Yongin-si (KR)

(21) Appl. No.: 19/419,032

(22) Filed: Dec. 14, 2025

(30) Foreign Application Priority Data
Feb. 26, 2025 (KR) 10-2025-0024911

(51) Int. Cl. B41J 2/14; B41J 2/16

(52) U.S. Cl. CPC B41J 2/1433; B41J 2/162; B41J 2/1628; B41J 2/1632; B41J 2/164; B41J 2/14201; B41J 2202/03

(57) ABSTRACT

An inkjet printing head includes a head unit and a nozzle unit. The nozzle unit is disposed below the head unit. The nozzle unit includes a base layer, a liquid-repellent pattern, a plurality of particles, a planarization layer, and a liquid-repellent layer. The base layer is adjacent to the head unit. The liquid-repellent pattern is disposed below the base layer and includes a plurality of liquid-repellent parts, each including a liquid-repellent material, and spaced apart from one another. The plurality of particles are disposed below the liquid-repellent pattern, and each of the plurality of particles overlaps with a corresponding liquid-repellent part among the plurality of liquid-repellent parts. The planarization layer is disposed below the base layer, covers the liquid-repellent pattern and the plurality of particles and includes a first inorganic material. The liquid-repellent layer is disposed below the planarization layer and includes a liquid-repellent material.

This application claims priority to Korean Patent Application No. 10-2025-0024911, filed on February 26, 2025, and all the benefits accruing therefrom under 35 U.S.C. §119, the content of which in its entirety is herein incorporated by reference.

### BACKGROUND

### 1. Field

The present disclosure relates to an inkjet printing head, an inkjet printing device including the inkjet printing head, and a method of manufacturing an inkjet printing head. Particularly, the present disclosure relates to an inkjet printing head providing a flat surface which covers a contaminant substance on a surface of a nozzle, an inkjet printing device including the inkjet printing head, and a method of manufacturing an inkjet printing head.

### 2. Description of the Related Art

An inkjet printing device may be used for precise deposition of a material during a process of forming an organic material layer, a light-emission layer, and a color filter of a display device. In order to improve precision and consistency of a product by an inkjet printing device, spray precision during a process of ink spraying is important. Particularly, liquid-repellency property of a surface of a nozzle may be a key factor in determining the spray precision.

A contaminant substance present on a surface of a nozzle may increase roughness of the surface of the nozzle. Accordingly, liquid-repellency property of the surface of the nozzle may be deteriorated due to the contaminant substance. Spray precision cannot be maintained in a nozzle with deteriorated liquid-repellency and an inkjet printing device including the nozzle, and their usable period may be shortened.

### SUMMARY

An object of the present disclosure is to provide an inkjet printing head with the improved roughness of a surface of a nozzle, an inkjet printing device including the inkjet printing head, and a method of manufacturing an inkjet printing head. Particularly, an object of the present disclosure is to improve liquid-repellency property of an inkjet printing head by providing a planarization layer covering a contaminant substance on a surface of a nozzle.

An inkjet printing head according to an embodiment of the present disclosure may include a head unit and a nozzle unit. The nozzle unit may be disposed below the head unit. The nozzle unit may include a base layer, a liquid-repellent pattern, a plurality of particles, a planarization layer, and a liquid-repellent layer. The base layer may be adjacent to the head unit. The liquid-repellent pattern may be disposed below the base layer. The liquid-repellent pattern may include a plurality of liquid-repellent parts, each of the plurality of liquid-repellent parts including a liquid-repellent material. The plurality of liquid-repellent parts may be spaced apart from one another. The plurality of particles may be disposed below the liquid-repellent pattern and each of the plurality of particles may overlap with a corresponding liquid-repellent part among the plurality of liquid-repellent parts. The planarization layer may be disposed below the base layer, cover the liquid-repellent pattern and the plurality of particles, and include a first inorganic material. The liquid-repellent layer may be disposed below the planarization layer and include a liquid-repellent material.

In an embodiment, a flatness deviation of a lower surface of the planarization layer may be smaller than a flatness deviation of an upper surface of the planarization layer.

In an embodiment, a distance from a lower surface of the base layer to a lower surface of any one of the plurality of particles may be defined as a first distance, and a distance from the lower surface of the base layer to the lower surface of the planarization layer may be defined as a second distance. The first distance may be smaller than the second distance.

In an embodiment, the first inorganic material may include at least one of silicon oxide (SiO₂), aluminum oxide (Al₂O₃), or silicon (Si).

In an embodiment, the plurality of particles may each include at least one of a compound of epoxy, a compound of aluminum (Al), a compound of carbon (C), and a compound of fluorine (F).

In an embodiment, the inkjet printing head may further include an intermediate layer interposed between the base layer and the liquid-repellent pattern and including a second inorganic material.

In an embodiment, the second inorganic material may include at least one of silicon (SiOₓ) or silicon oxycarbide (SiOC).

In an embodiment, the inkjet printing head may further include a first auxiliary layer interposed between the planarization layer and the liquid-repellent layer and including a third inorganic material.

In an embodiment, the third inorganic material may include at least one of silicon (SiOₓ) or silicon oxycarbide (SiOC).

In an embodiment, the inkjet printing head may further include a second auxiliary layer interposed between the planarization layer and the first auxiliary layer.

In an embodiment, the second auxiliary layer may include at least one of aluminum oxide (Al₂O₃), silicon oxide (SiOₓ), or silicon nitride (SiNₓ).

An inkjet printing device according to an embodiment of the present disclosure may include a stage, a head unit, and a nozzle unit. The stage may have a substrate mounted thereon. The head unit may be disposed on the stage and provide ink. The nozzle unit may be disposed below the head unit and define a passage for spraying ink on a substrate. The nozzle unit may include a base layer, a liquid-repellent pattern, a plurality of particles, a planarization layer, and a liquid-repellent layer. The base layer may include an inner surface adjacent to the passage and an outer surface adjacent to the stage. The liquid-repellent pattern may be disposed below the outer surface and include a plurality of liquid-repellent parts, each of the plurality of liquid-repellent parts including a liquid-repellent material. The plurality of liquid-repellent parts may be spaced apart from one another. The plurality of particles may be disposed below the liquid-repellent pattern, and each of the plurality of particles may overlap with a corresponding liquid-repellent part among the plurality of liquid-repellent parts. The planarization layer may be disposed below the outer surface, cover the liquid-repellent pattern and the plurality of particles, and include an inorganic material. The liquid-repellent layer may be disposed below the planarization layer and include a liquid-repellent material.

In an embodiment, a flatness deviation of a lower surface of the planarization layer may be smaller than a flatness deviation of an upper surface of the planarization layer.

In an embodiment, a distance from the outer surface to a lower surface of any one of the plurality of particles may be defined as a first distance, and a distance from the outer surface to the lower surface of the planarization layer may be defined as a second distance. The first distance may be smaller than the second distance.

In an embodiment, the inorganic material may include at least one of silicon oxide (SiO₂), aluminum oxide (Al₂O₃), or silicon (Si).

A method of manufacturing an inkjet printing head according to an embodiment of the present disclosure may include preparing, forming a liquid-repellent pattern, forming a coating layer, forming a planarization layer, and forming a second liquid-repellent layer. In the preparing, a basic nozzle unit including a base layer, a first liquid-repellent layer disposed on the base layer and including a liquid-repellent material, and a plurality of particles disposed on the first liquid-repellent layer and spaced apart from one another may be prepared. In the forming a liquid-repellent pattern, portions of the first liquid-repellent layer which are non-overlapping with the plurality of particles may be removed to form the liquid-repellent pattern, wherein the portions of the first liquid-repellent layer which are non-overlapping with the plurality of particles are different from portions of the first liquid-repellent layer which are overlapping with the plurality of particles. In the forming a coating layer, a coating layer covering the liquid-repellent pattern and the plurality of particles may be formed, and the coating layer may include an inorganic material. In the forming a planarization layer, a portion of the coating layer protruding in a direction away from the base layer may be removed to form a planarization layer providing a planarized surface. In the forming a second liquid-repellent layer, a second liquid-repellent layer including a liquid-repellent material may be formed on the planarization layer.

In an embodiment, the forming of the liquid-repellent pattern may include removing, using O₂ plasma, the portion of the first liquid-repellent layer which is non-overlapping with the plurality of particles.

In an embodiment, the forming of the planarization layer may include removing, by a chemical mechanical polishing method, the portion of the coating layer which protrudes in a direction away from the base layer.

In an embodiment, the method of manufacturing the inkjet printing head may further include forming an auxiliary layer which is disposed on the planarization layer, between the forming of the planarization layer and the forming of the second liquid-repellent layer.

In an embodiment, the auxiliary layer may include at least one of an organic material or an inorganic material.

According to one embodiment of the present disclosure, a planarization layer covering a contaminant material present on a surface of a nozzle of an inkjet printing head may be formed to reduce roughness of the surface of the nozzle.

In some aspects, according to an embodiment of the present disclosure, a liquid-repellent structure may be applied after formation of a planarization layer to improve liquid-repellency property of an inkjet printing head.

### BRIEF DESCRIPTION OF THE DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1 is a perspective view of an inkjet printing device according to an embodiment of the present disclosure;

FIG. 2 is a plan view of an inkjet printing device according to an embodiment of the present disclosure;

FIG. 3 is an example magnified view of a nozzle unit of an inkjet printing device according to an embodiment of the present disclosure;

FIG. 4 is an example magnified view of the area AA illustrated in FIG. 3;

FIG. 5 is an example illustration of another embodiment corresponding to the area AA illustrated in FIG. 3;

FIG. 6 is an example illustration of yet another embodiment corresponding to the area AA illustrated in FIG. 3;

FIG. 7 is a flow chart of a method of manufacturing an inkjet printing head according to an embodiment of the present disclosure; and

FIG. 8A through FIG. 8G are example illustrations of each step of a method of manufacturing an inkjet printing head according to an embodiment of the present disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are described herein, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, and the like illustrated in the drawings.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Terms such as “first” and “second” shall be interpreted to distinguish one from another in case that there are various characteristics, numbers, steps, operations, elements, parts or combinations thereof. As an example, a first element and a second element may be rephrased as a second element and a first element.

Herein, a first direction through a third direction DR1, DR2, and DR3 may be defined to describe an inkjet printing device according to an embodiment of the present disclosure. An inkjet printing device may have a substrate disposed on a plane defined by a first direction DR1 and a second direction DR2 and be configured to spray ink on the substrate. The third direction may be defined as a direction of a thickness of the substrate, and the first direction through the third DR1, DR2, and DR3 may be orthogonal to one another.

Herein, when an element, such as a layer, a film, a region, and a plate, is “on” or “above” another element, this includes not only a case of being “directly on” the other element, but also a case of having yet another element therebetween. In the contrary, when an element, such as a layer, a film, a region, and a plate, is “below” or “under” another element, this includes not only a case of being “directly under” the other element, but also a case of having yet another element therebetween. Furthermore, herein, when an element is disposed “on” another element, this includes not only disposition above the other element but also disposition below the other element.

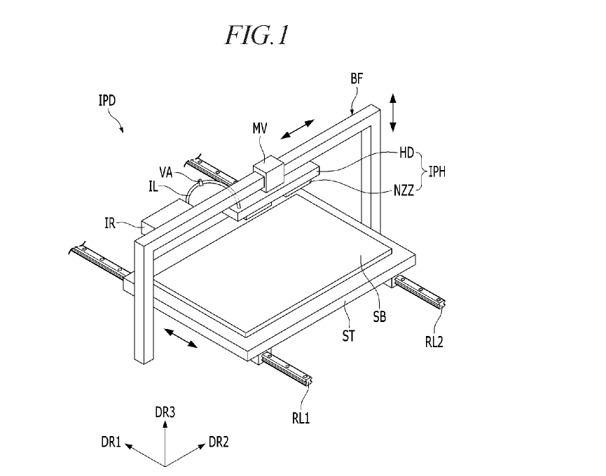

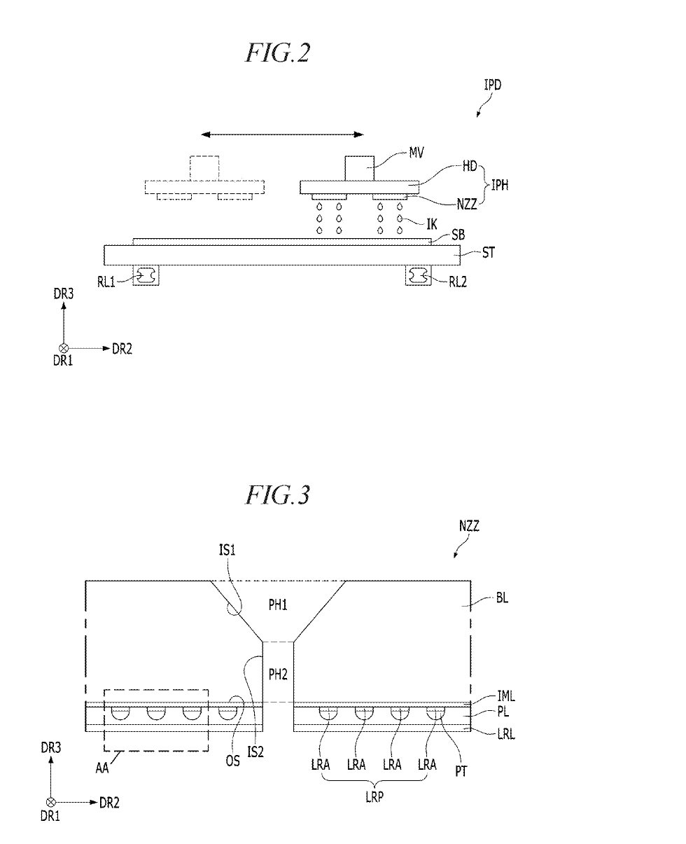

FIG. 1 is a perspective view of an inkjet printing device IPD according to an embodiment of the present disclosure. FIG. 2 is a plan view of an inkjet printing device IPD according to an embodiment of the present disclosure. Referring to FIG. 1 and FIG. 2, an inkjet printing device IPD according to an embodiment may include a stage ST, a plurality of rails RL1 and RL2, a base frame BF, a driving unit MV, an inkjet printing head IPH, an ink storage IR, a connection tube IL, and a valve VA. A substrate may be disposed on the stage ST. The inkjet printing device IPD may further include a probe device (not illustrated) and a control unit (not illustrated).

The stage ST may provide an area for disposition of a substrate SB. A shape of the stage ST may correspond to a planar shape of the substrate SB. The stage may be reciprocally moved in the first direction DR1 by the plurality of rails RL1 and RL2. As the stage ST is moved, the substrate SB may be moved in the first direction DR1, and ink IK may be sprayed onto the substrate SB. In an embodiment of the present disclosure, the substrate SB may be a substrate for an inorganic light-emitting display device, an organic light-emitting display device, a micro light-emitting display device, or a quantum dot light-emitting display device. In another embodiment, the substrate SB may be formed of a semiconductor or a glass for manufacturing a display device, but embodiments of the present disclosure are not limited thereto.

The plurality of rails RL1 and RL2 may include a first rail RL1 and a second rail RL2. The first rail RL1 may be disposed on one side below the inkjet printing device IPD. The second rail RL2 may be disposed on another side below the inkjet printing device IPD. A position, a shape, and an operation method of the plurality of rails RL1 and RL2 are not limited to what is illustrated in FIG. 1.

A probe device (not illustrated) may be disposed on the stage ST. A substrate SB may be disposed on the prove device. The probe device may be configured to generate an electric field on the substrate SB and align particles included in ink IK through the electric field.

The base frame BF may have a stick shape extending in the second direction DR2. In some aspects, the base frame BF may extend in the third direction DR3 and have a stick shape spaced apart from a ground and having a pre-determined height. The base frame BF may have a structure configured to stably spray ink IK on the stage ST. The base frame BF may be configured to support the driving unit MV. A shape of the base frame BF is not limited to what is illustrated in FIG. 1.

The driving unit MV may be mounted on the base frame BF. Particularly, the driving unit MV may have a shape surrounding the base frame BF and move along the base frame BF in the second direction DR2. The driving unit MV may be connected to the inkjet printing head IPH and move the inkjet printing head IPH in the second direction DR2. Accordingly, the inkjet printing device IPH may be configured to evenly perform a printing process on an entire area of the substrate SB disposed on the stage ST.

In some aspects, the driving unit MV may move the inkjet printing head IPH in the third direction DR3. The driving unit MV may be configured to adjust a separation distance between the inkjet printing head IPH and the stage ST in the third direction DR3. The separation distance between the inkjet printing head IPH and the stage ST may be adjusted within a range providing a space supportive of a printing process when the substrate SB is disposed on the stage ST.

The inkjet printing head IPH may be configured to print ink IK on the substrate SB. The inkjet printing head IPH may be configured to spray, eject, or print pre-determined ink IK upon operation of the inkjet printing device IPD. The inkjet printing head IPH may be configured to spray ink IK provided from the ink storage IR on the substrate SB provided on the stage ST.

The inkjet printing head IPH may be disposed on the stage ST. The inkjet printing head IPH may be mounted on the base frame BF and moved by the driving unit MV. A connection method of the inkjet printing head IPH to the driving unit MV is not particularly limited.

The inkjet printing head IPH may include a head unit HD and a nozzle unit NZZ. In FIG. 1, one head unit HD is exemplarily illustrated, but an amount of the head unit HD is not limited to what is illustrated in the figure. The inkjet printing head IPH may include a plurality of head units HD and a plurality of nozzle units NZZ. The plurality of head units HD may be aligned in one direction. The plurality of head units HD may be arranged in one row or multiple rows.

The head unit HD may be configured to receive ink IK from the ink storage IR. The ink IK may circulate through the ink storage IR and the head unit HD. Some of the ink IK provided to the head unit HD may be ejected to the substrate SB from the head unit HD, and the other may be supplied back to the ink storage IR.

The ink storage IR may be connected to the head unit HD through the connection tube IL. As an example, the ink storage IR may be configured to supply ink IK to the head unit HD through the connection tube IL. A flow rate of the supplied ink IK may be adjusted by the valve VA.

The ink storage IR may be mounted on the base frame BF. A position or a shape of the ink storage IR is not particularly limited. As an example, the ink storage IR may be disposed through a separate device or disposed in various ways within a range of being connected to the head unit HD.

The head unit HD may further include a piezoelectric device unit (not illustrated) and a pressure chamber (not illustrated). An ejected amount of ink IK through each nozzle unit NZZ may be adjusted by the piezoelectric device unit. The piezoelectric device unit may be configured to control a pressure applied to the pressure chamber based on a voltage applied to the piezoelectric device unit. Upon applying pressure to the pressure chamber, ink IK may be sprayed through the nozzle unit NZZ.

Ink IK may be provided in a form of a solution or colloid. Ink IK may include a solvent and a plurality of particles dispersed in the solvent. As an example, the solvent may be acetone, water, alcohol, toluene, propylene glycol, or propylene glycol methyl acetate, but embodiments of the present disclosure are not limited thereto.

The nozzle unit NZZ may be disposed adjacent to the head unit HD. Particularly, the nozzle unit NZZ may be disposed below the head unit HD. In FIG. 1 and FIG. 2, two nozzle units NZZ are exemplarily illustrated, but an amount of the nozzle units NZZ is not limited to what is illustrated in the figures. An amount and an arrangement of the nozzle units NZZ may be limitlessly modified.

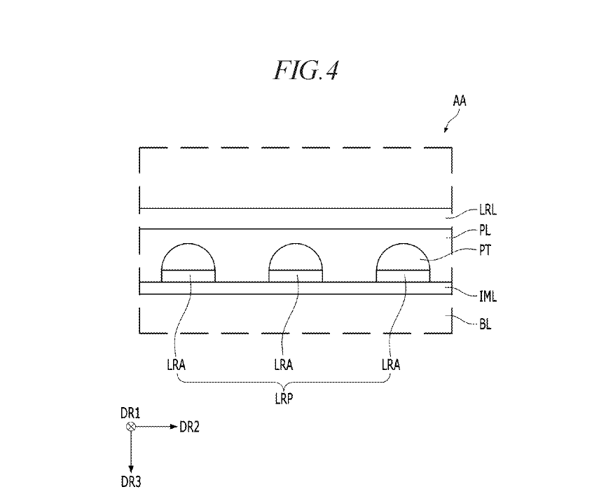

A surface of a nozzle unit NZZ affects spray precision during a process of spraying ink IK. Particularly, in order to reduce ink IK attached to or remaining on a surface of a nozzle unit NZZ during a process of spraying ink IK, embodiments of the present disclosure include achieving a liquid repellency property or hydrophobicity for an outer surface of a nozzle unit NZZ. Particularly, in case that a liquid-repellent film having liquid-repellency is formed on an outer surface of the nozzle unit NZZ, ink-wetting may be prevented, and straightness of jetted ink IK may be achieved. In order to achieve the above, the nozzle unit NZZ may include a coated film formed of a liquid-repellent material. Detailed description about a configuration of a nozzle unit NZZ will be described with reference to FIG. 3.

An inkjet printing device IPD may include a control unit (not illustrated). The control unit may be connected to each element of the inkjet printing device IPD and configured to control an overall operation of the inkjet printing device IPD. For example, the control unit may be electrically connected to the driving unit MV to move the inkjet printing head IPH. In some aspects, the control unit may be electrically connected to the head unit HD and configured to control the head unit HD to spray ink IK.

The driving unit may include a processor, a memory, and a storage. An operation, such as a printing operation, of the inkjet printing device IPD may be implemented by firmware or software. For example, the firmware may be stored in the storage and loaded to the memory upon operation of the firmware. The processor may be configured to operate the firmware loaded to the memory. However, embodiments of the present disclosure are not limited thereto, and the control unit may be composed of an individual hardware configured to perform an operation. For example, the control unit may be implemented by an exclusive logic circuit, such as Field Programmable Gate Array (FPGA) and Application Specific Integrated Circuit (ASIC).

FIG. 3 is an example magnified view of a nozzle unit NZZ of an inkjet printing device IPD according to an embodiment of the present disclosure. Referring to FIG. 3, a nozzle unit NZZ according to an embodiment of the present disclosure may include a plurality of layers disposed below the head unit HD (see FIG. 2). The nozzle unit NZZ may include a base layer BL, an intermediate layer IML, a plurality of liquid-repellent units LRA, a liquid-repellent pattern LRP, a plurality of particles PT, a planarization layer PL, and a liquid-repellent layer LRL. A shape of the nozzle unit NZZ is not limited to what is illustrated in FIG. 3.

A plurality of passageways PH1 and PH2, through which ink is sprayed, may be defined in the nozzle unit NZZ. The plurality of passageways PH1 and PH2 may include a first passageway PH1 and a second passageway PH2. The first passageway PH1 may be adjacent to the head unit and have a shape in which its cross-sectional area becomes narrower toward the second passageway PH2. The second passageway PH2 may be adjacent to the substrate SB (see FIG. 1) disposed on the stage ST (see FIG. 1). Ink may be jetted through the first passageway PH1 and the second passageway PH2 in a shape of an ink droplet.

The base layer BL may be disposed adjacent to the head unit HD. The base layer BL may include a first inner surface IS1 adjacent to the first passageway PH1, a second inner surface IS2 adjacent to the second passageway PH2, and an outer surface OS adjacent to the stage ST.

The inner surfaces IS1 and IS2 of the base layer BL may be hydrophilic to facilitate flow of ink. The outer surface OS of the base layer BL may have liquid -repellent property or hydrophobicity to jet the ink along the second passageway PH2 without flowing along the outer surface OS. Accordingly, a liquid-repellent film or a coating layer having liquid-repellency may be formed on the outer surface OS of the base layer BL.

The base layer BL may be composed of a substrate made from a material with good processability. For example, the base layer BL may include a metallic material, such as iron (Fe), chromium (Cr), or nickel (Ni). In another embodiment, the base layer BL may include an organic material, such as polyimide.

The intermediate layer IML may be disposed below the base layer BL. The intermediate layer IML may be disposed adjacent to the outer surface OS. The intermediate layer IML may include a first inorganic material. The first inorganic material may include at least one of silicon oxide (SiOₓ) or silicon oxycarbide (SiOC). However, embodiments of the present disclosure are not limited thereto. In an embodiment of the present disclosure, the intermediate layer IML may play a role as an adhesive layer for stable attachment of the liquid-repellent pattern LRP. The intermediate layer IML may serve as an adhesive layer formed to enhance landing precision of the liquid-repellent pattern LRP. For example, the intermediate layer IML may be a thin film having a thickness smaller than or equal to 5 nm. The intermediate layer IML may be omitted.

The liquid-repellent pattern LRP may be disposed below the base layer BL. In another embodiment, the liquid-repellent pattern LRP may be disposed below the base layer BL, with the intermediate layer IML between liquid-repellent pattern LRP and the base layer BL. The liquid-repellent pattern LRP may include a plurality of liquid-repellent parts LRA, each of which includes a liquid-repellent material. The plurality of liquid-repellent parts LRA may be spaced apart from one another. The liquid-repellent material may be composed of a fluorine-containing monomer or a fluorine-containing polymer, and particularly include a fluorine-containing aliphatic polycarbonate.

The plurality of particles PT may be disposed below the liquid-repellent pattern LRP. The plurality of particles PT may each be disposed to overlap with a corresponding liquid-repellent part LRA among the plurality of liquid-repellent parts. In on embodiment of the present disclosure, the plurality of particles PT may be an attached contaminant material during a process of manufacturing a nozzle unit NZZ. Accordingly, the plurality of particles PT may each be spaced part from one another. In some aspects, it may be difficult to mechanically remove the plurality of particles PT or even with acetone or ethanol. For example, the plurality of particles PT may each include at least one of a compound of epoxy, a compound of aluminum (Al), a compound of carbon (C), or a compound of fluorine (F). However, these are examples, and embodiments of the present disclosure are not limited thereto. In some aspects, heights of the plurality of particles PT may be greater than or equal to 10 nm and smaller than or equal to 50 nm.

The planarization layer PL may be disposed below the base layer BL or the intermediate layer IML. The planarization layer PL may cover the plurality of particles PT to provide a flat surface. The planarization layer PL may include a second inorganic material. The second inorganic material may include at least one of silicon oxide (SiO₂), aluminum oxide (Al₂O₃), or silicon (Si). However, embodiments of the present disclosure are not limited thereto.

A flatness deviation of a lower surface of the planarization layer PL, which is furthest from the outer surface OS, may be smaller than a flatness deviation of an upper surface of the planarization layer PL, which is adjacent to the outer surface OS. A difference between the flatness deviation of the upper surface and the lower surface of the planarization layer PL may be due to the plurality of particles PT. Accordingly, a distance from the outer surface OS to a lower surface of any one of the plurality of particles PT may be smaller than a distance from the outer surface OS to a lower surface of the planarization layer PL. For example, the distance from the outer surface OS to the lower surface of the planarization layer PL may be greater than or equal to 40 nm and smaller than or equal to 100 nm. The distance from the outer surface OS to the lower surface of the planarization layer PL may be set to have the planarization layer PL cover the plurality of particles PT.

The liquid-repellent layer LRL may be disposed below the planarization layer PL. The liquid-repellent layer LRL may include a liquid-repellent material. The liquid-repellent material may be formed of a fluorine-containing monomer or a fluorine-containing polymer and particularly include a fluorine-containing aliphatic polycarbonate. For example, the liquid-repellent layer LRL and the plurality of liquid-repellent parts LRA may be formed of the same liquid-repellent material, or may be formed of different liquid-repellent materials. Accordingly, the liquid-repellent layer LRL may be configured to jet ink on a desired position without attachment to or dispersion on a surface of the liquid-repellent layer LRL. Accordingly, the inkjet printer head IPH (see FIG. 2) may have excellent jetting efficiency and precision.

The intermediate layer IML, the liquid-repellent pattern LRP, the planarization layer PL, and the liquid-repellent layer LRL may be deposited in a form of a thin film through sputtering, physical vapor deposition, chemical vapor deposition, or atomic layer deposition. However, these are mere examples, and embodiments of the present disclosure are not limited thereto.

FIG. 4 through FIG. 6 are examples magnified illustration of the area AA illustrated in FIG. 3. FIG. 4 through FIG. 6 illustrates that the area AA illustrated in FIG. 3 is rotated to face an opposite direction to the third direction DR3, i.e., by 180 degrees. For convenience of the description, the reference for the third direction DR3 will be redefined in FIG. 4 and subsequent figures, differing from the description in FIG. 3. That is, FIG. 3 illustrates that the intermediate layer IML is disposed below the base layer BL, but FIG. 3 and subsequent figures illustrate that the intermediate layer IML is disposed on the base layer BL for convenience.

Referring to FIG. 4, the intermediate layer IML may be disposed on the base layer BL. The liquid-repellent pattern LRP may be disposed on the base layer BL, with the intermediate layer IML between the liquid-repellent pattern LRP and the base layer BL. The plurality of particles PT may be disposed on the liquid-repellent pattern LRP. The planarization layer PL may be disposed on the base layer BL or the intermediate layer IML and cover the liquid- repellent pattern LRP and the plurality of particles PT. In some aspects, the planarization layer PL may provide a flat surface above. The liquid-repellent layer LRL may be disposed on the planarization layer PL.

The descriptions about the base layer BL, the intermediate layer IML, the plurality of liquid-repellent parts LRA, liquid-repellent pattern LRP, the plurality of particles PT, the planarization layer PL, and the liquid-repellent layer LRL in FIG. 4 are the same as the descriptions for FIG. 3.

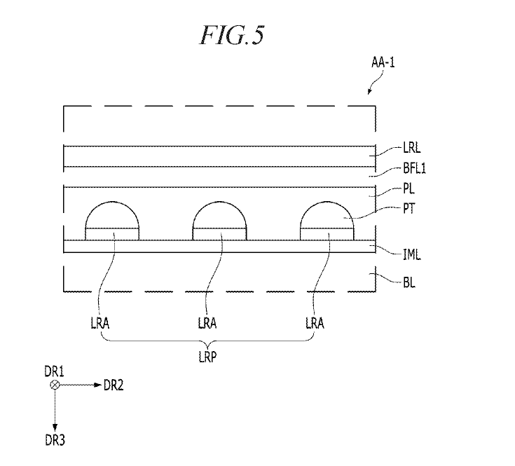

FIG. 5 is an example illustration of another embodiment (AA-1) corresponding to the area AA illustrated in FIG. 3. Referring to FIG. 5, the first auxiliary layer BFL1 may be disposed between the planarization layer PL and the liquid-repellent layer LRL. The first auxiliary layer BFL1 may include a third inorganic material. The third inorganic material may include at least one of silicon oxide (SiOₓ) or silicon oxycarbide (SiOC). However, embodiments of the present disclosure are not limited thereto.

The first auxiliary layer BFL1 may function as an adhesive layer for stable formation of the liquid-repellent layer LRL. The first auxiliary layer BFL1 may be an adhesive layer formed to improve landing precision of the liquid-repellent layer LRL. For example, the first auxiliary layer BFL1 may be a thin film having a thickness smaller than or equal to 10 nm.

The first auxiliary layer BFL1 may be deposited in a form of a thin film through sputtering, physical vapor deposition, chemical vapor deposition, or atomic layer deposition. However, these are examples, and embodiments of the present disclosure are not limited thereto.

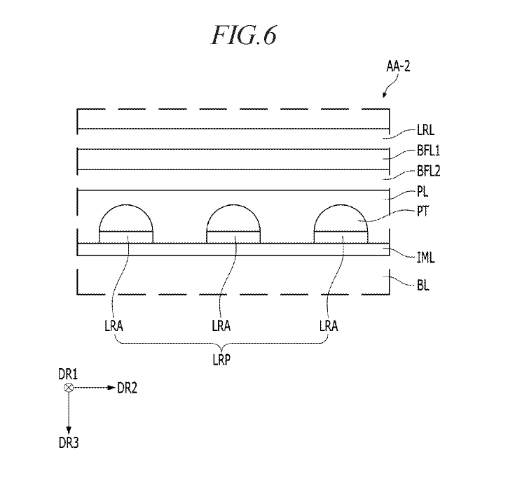

FIG. 6 is an example illustration of another embodiment (AA-2) corresponding to the area AA illustrated in FIG. 3. Referring to FIG. 6, a second auxiliary layer BFL2 may be interposed between the planarization layer PL and the first auxiliary layer BFL1. The second auxiliary layer BFL2 may include metallic oxide. The second auxiliary layer BFL2 may include at least one of aluminum oxide (Al₂O₃), silicon oxide (SiOₓ), or silicon nitride (SiNₓ). However, embodiments of the present disclosure are not limited thereto.

The second auxiliary layer BFL2 may be formed to improve liquid-repellency property, and chemical resistance and durability of the nozzle unit. In some aspects, the second auxiliary layer BFL2 may function as an adhesive layer for stable formation of a liquid-repellent film between the planarization layer PL and the first auxiliary layer BFL1. For example, the second auxiliary layer BFL2 may have a thickness smaller than or equal to 50 nm, but embodiments of the present disclosure are not limited thereto.

The second auxiliary layer BFL2 may be deposited in a form of a thin film through sputtering, physical vapor deposition, chemical vapor deposition, or atomic layer deposition. However, these are examples, and embodiments of the present disclosure are not limited thereto.

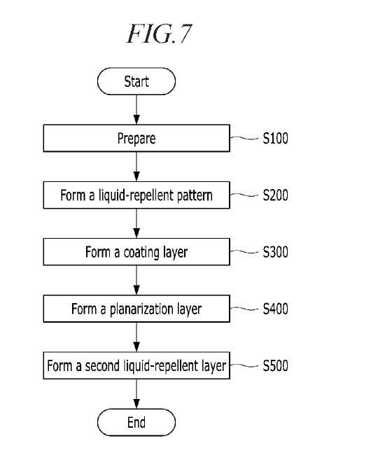

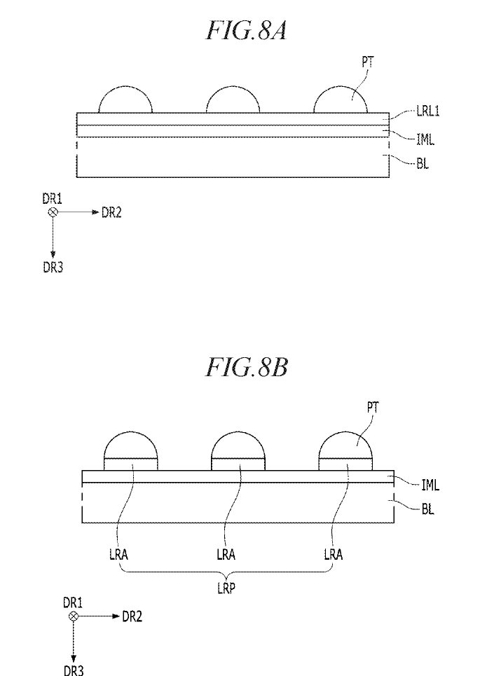

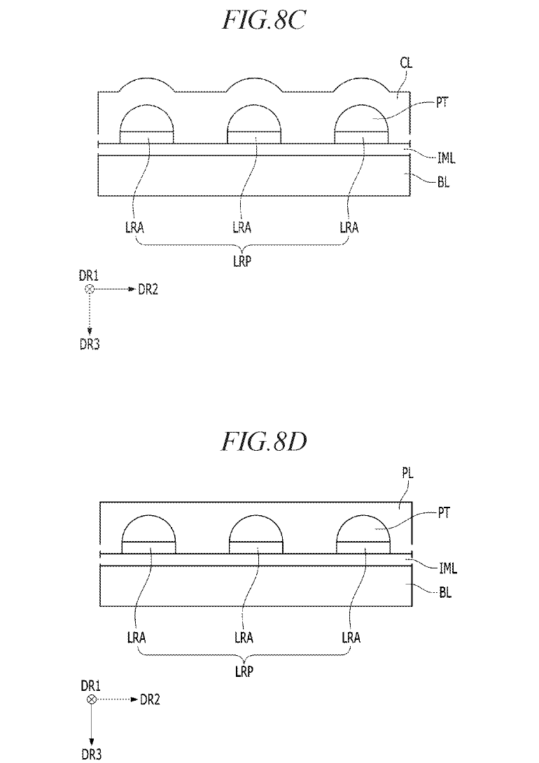

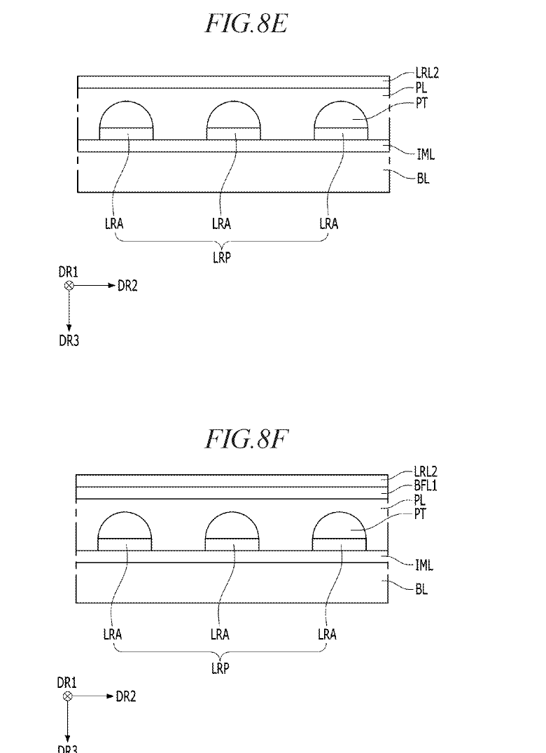

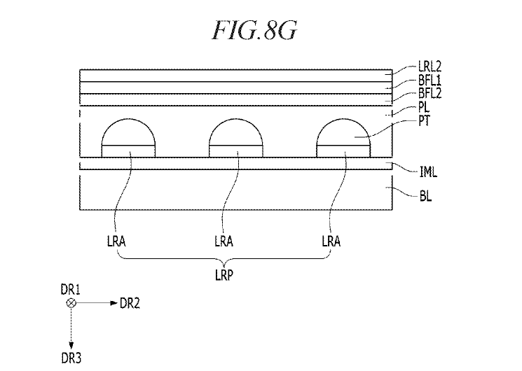

FIG. 7 is a flow chart of a method of manufacturing an inkjet printing head according to an embodiment of the present disclosure. FIG. 8A through FIG. 8G are example illustrations of each step of a method of manufacturing an inkjet printing head. FIG. 8A through FIG. 8G are described with reference to FIG. 7. In some aspects, FIG. 8A through FIG. 8G may be understood as a portion corresponding to the nozzle unit NZZ illustrated in FIG. 3 and interpreted to have each layer laminated in a jetting direction of ink.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be prepared,” “may be formed,” “may be disposed,” and the like include methods, processes, and techniques for preparing, forming, positioning, and modifying the element, and the like in accordance with example aspects described herein.

Referring to FIG. 7, a method of manufacturing an inkjet printing head may include preparing S100, forming a liquid-repellent pattern S200, forming a coating layer S300, forming a planarization layer S400, and forming a second liquid-repellent layer S500.

In an embodiment of the present disclosure, a method of manufacturing an inkjet printing head as performed may minimize an effect on liquid-repellency property by a contaminant material present on a surface of the inkjet printing head IPH (see FIG. 1), particularly a surface of the nozzle unit NZZ (see FIG. 1). The method of manufacturing an inkjet printing head may reduce surface roughness and provide a process which applies a structure having liquid-repellent property on the inkjet printing head surface for improvement of liquid-repellent property.

Referring to FIG. 8A, in the preparing S100, a base nozzle unit may be prepared. The base nozzle may include a base layer BL, an intermediate layer IML disposed on the base layer BL, a first liquid-repellent layer LRL1 disposed on the intermediate layer IML, and a plurality of particles PT each spaced apart from one another on the first liquid-repellent layer LRL1. Here, the intermediate layer IML may be omitted. In some aspects, the first liquid-repellent layer LRL1 may include a liquid-repellent material. The liquid-repellent material may be formed of fluorine-containing monomer or fluorine-containing polymer and particularly include fluorine-containing aliphatic polycarbonate.

In a base nozzle unit, a surface may not be uniform due to the plurality of particles PT. Accordingly, in the case of using an inkjet printing head applied with a base nozzle unit, the liquid-repellency property may be deteriorated, ink may be dispersed on the inkjet printing head surface, and spray precision may be deteriorated.

Referring to FIG. 8A and 8B, in the forming a liquid-repellent pattern S200, the liquid-repellent pattern LRP may be formed on the base layer BL or the intermediate layer IML. Portions other than portions of the first liquid-repellent layer LRL1 overlapping with the plurality of particles PT may be removed to form a plurality of liquid-repellent parts LRA. The plurality of liquid-repellent parts LRA may overlap with the plurality of particles PT, each spaced apart from one another. A liquid-repellent pattern LRP may include a plurality of liquid-repellent parts LRA. In the forming a liquid-repellent pattern S200, a plurality of liquid-repellent parts LRA may be formed by removing portions of the first liquid-repellent layer LRL1 which are not overlapping with the plurality of particles PT, through a surface treatment process using O₂ plasma, i.e., an ashing process. However, a method of forming a liquid-repellent pattern LRP by removing a portion of the first liquid-repellent layer LRL1 is not limited thereto.

Referring to FIG. 8C, in the forming a coating layer S300, a coating layer CL covering the liquid-repellent pattern LRP and the plurality of particles PT may be formed. As the coating layer CL has a shape of covering the plurality of particles PT, the coating layer may have a shape protruding in the third direction DR3. The coating layer CL may include an inorganic material and include at least one of silicon oxide (SiO₂), aluminum oxide (Al₂O₃), or silicon (Si). However, embodiments of the present disclosure are not limited thereto.

The coating layer CL may be deposited in a form of a thin film through, for example, sputtering, physical vapor deposition, chemical vapor deposition, or atomic layer deposition. However, these are examples, and embodiments of the present disclosure are not limited thereto.

Referring to FIG. 8C and 8D, in the forming a planarization layer S400, a portion of the coating layer CL protruding above (i.e., protruding in a negative direction DR3 away from the base layer BL) may be removed to form a planarization layer PL providing a flat surface. In the forming a planarization layer S400, a portion of the coating layer CL protruding above may be removed through a chemical mechanical polishing method. However, a method of forming a flat surface by removing a portion of the coating layer CL protruding above is not limited thereto.

As a flat surface is provided above the planarization layer PL, a flatness of a lower surface of the planarization layer, i.e., a surface adjacent to the base layer BL, may be worse than a flatness of an upper surface of the planarization layer PL, that is a surface furthest from the base layer BL.

Referring to FIG. 8E, in the forming a second liquid-repellent layer S500, a second liquid-repellent layer LRL2 may be formed. The second liquid-repellent layer LRL2 may include a liquid-repellent material. The liquid-repellent material may be formed of a fluorine-containing monomer or a fluorine-containing polymer, and particularly include fluorine-containing aliphatic polycarbonate. As the second liquid-repellent layer LRL2 is disposed on the planarization layer PL, a surface of the inkjet printing head may have reduced roughness and improved liquid-repellency property.

Referring to FIG. 8F and FIG. 8G, a method of manufacturing an inkjet printing head may further include forming an auxiliary layer between the forming a planarization layer S400 and the forming a second liquid-repellent layer S500. In the forming an auxiliary layer, a first auxiliary layer BFL1 and a second auxiliary layer BFL2 disposed on the planarization layer PL may be formed. The first auxiliary layer BFL1 and the second auxiliary layer BFL2 may each include at least one of an organic material or an inorganic material. For example, the first auxiliary layer BFL1 may include at least one of silicon oxide (SiOₓ) or silicon oxycarbide (SiOC). In some aspects, the second auxiliary layer BFL2 may include metallic oxide.

The first auxiliary layer BFL1 and the second auxiliary layer BFL2 may each be deposited in a form of a thin film through sputtering, physical vapor deposition, chemical vapor deposition or atomic layer deposition. However, these are examples, and embodiments of the present disclosure are not limited thereto.

While certain embodiments of the present disclosure have been described herein, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. An inkjet printing head comprising:
a head unit; and
a nozzle unit disposed below the head unit,
wherein the nozzle unit comprises:
a base layer adjacent to the head unit;
a liquid-repellent pattern disposed below the base layer and comprising a plurality of liquid-repellent parts each comprising a liquid-repellent material, wherein the plurality of liquid-repellent parts are spaced apart from one another;
a plurality of particles disposed below the liquid-repellent pattern, each of the plurality of particles overlapping with a corresponding liquid-repellent part among the plurality of liquid-repellent parts;
a planarization layer disposed below the base layer, covering the liquid-repellent pattern and the plurality of particles, and comprising a first inorganic material; and
a liquid-repellent layer disposed below the planarization layer and comprising a liquid-repellent material.

2. The inkjet printing head of claim 1, wherein a flatness deviation of a lower surface of the planarization layer is smaller than a flatness deviation of an upper surface of the planarization layer.

3. The inkjet printing head of claim 1, wherein:
a distance from a lower surface of the base layer to a lower surface of any one of the plurality of particles is defined as a first distance,
a distance from the lower surface of the base layer to the lower surface of the planarization layer is defined as a second distance, and
the first distance is smaller than the second distance.

4. The inkjet printing head of claim 1, wherein the first inorganic material comprises at least one of silicon oxide (SiO₂), aluminum oxide (Al₂O₃), or silicon (Si).

5. The inkjet printing head of claim 1, wherein the plurality of particles each comprise at least one of a compound of epoxy, a compound of aluminum, a compound of carbon, and a compound of fluorine.

6. The inkjet printing head of claim 1, further comprising an intermediate layer interposed between the base layer and the liquid-repellent pattern and comprising a second inorganic material.

7. The inkjet printing head of claim 6, wherein the second inorganic material comprises at least one of silicon oxide (SiOₓ) or silicon oxycarbide (SiOC).

8. The inkjet printing head of claim 6, further comprising a first auxiliary layer interposed between the planarization layer and the liquid-repellent layer and comprising a third inorganic material.

9. The inkjet printing head of claim 8, wherein the third inorganic material comprises at least one of silicon oxide (SiOₓ) or silicon oxycarbide (SiOC).

10. The inkjet printing head of claim 8, further comprising a second auxiliary layer interposed between the planarization layer and the first auxiliary layer.

11. The inkjet printing head of claim 10, wherein the second auxiliary layer comprises at least one of aluminum oxide (Al₂O₃), silicon oxide (SiOₓ), or silicon nitride (SiNₓ).

12. An inkjet printing device comprising:
a stage mounted on a substrate;
a head unit which is disposed on the stage and provides ink; and
a nozzle unit disposed below the head unit, wherein the nozzle unit sprays the ink onto the substrate through a passageway defined in the nozzle unit,
wherein the nozzle unit comprises:
a base layer comprising an inner surface adjacent to the passageway and an outer surface adjacent to the stage;
a liquid-repellent pattern disposed below the outer surface and comprising a plurality of liquid-repellent parts each comprising a liquid-repellent material,
wherein the plurality of liquid-repellent parts are spaced apart from one another;
a plurality of particles disposed below the liquid-repellent pattern, each of the plurality of particles overlapping with a corresponding liquid-repellent part among the plurality of liquid-repellent parts;
a planarization layer disposed below the outer surface, covering the liquid-repellent pattern and the plurality of particles, and comprising an inorganic material; and
a liquid-repellent layer disposed below the planarization layer and comprising a liquid-repellent material.

13. The inkjet printing device of claim 12, wherein a flatness deviation of a lower surface of the planarization layer is smaller than a flatness deviation of an upper surface of the planarization layer.

14. The inkjet printing device of claim 13, wherein:
a distance from the outer surface to a lower surface of any one of the plurality of particles is defined as a first distance,
a distance from the outer surface to the lower surface of the planarization layer is defined as a second distance, and
the first distance is smaller than the second distance.

15. The inkjet printing device of claim 14, wherein the inorganic material comprises at least one of silicon oxide (SiO₂), aluminum oxide (Al₂O₃), or silicon (Si).

16. A method of manufacturing an inkjet printing head, the method comprising:
preparing a base nozzle unit comprising:
a base layer,
a first liquid-repellent layer disposed on the base layer and comprising a liquid-repellent material, and
a plurality of particles spaced apart on the first liquid-repellent layer;
forming a liquid-repellent pattern by removing a portion of the first liquid-repellent layer which is non-overlapping with the plurality of particles, wherein the portion of the first liquid-repellent layer which is non-overlapping with the plurality of particles is different from a portion of the first liquid-repellent layer which is overlapping with the plurality of particles;
forming a coating layer covering the liquid-repellent pattern and the plurality of particles, wherein the coating layer comprises an inorganic material;
forming a planarization layer providing a flat surface by removing a portion of the coating layer which protrudes in a direction away from the base layer; and
forming, on the planarization layer, a second liquid-repellent layer comprising a liquid-repellent material.

17. The method of claim 16, wherein the forming of the liquid-repellent pattern comprises removing, using O₂ plasma, the portion of the first liquid-repellent layer which is non-overlapping with the plurality of particles.

18. The method of claim 16, wherein the forming of the planarization layer comprises removing, by a chemical mechanical polishing method, the portion of the coating layer which protrudes in a direction away from the base layer.

19. The method of claim 16, further comprising forming an auxiliary layer which is disposed on the planarization layer, between the forming of the planarization layer and the forming of the second liquid-repellent layer.

20. The method of claim 19, wherein the auxiliary layer comprises at least one of an organic material or an inorganic material.
